(19) United States
(12) Patent Application Publication
(10) Pub. No.: US 2015/0296656 A1
(43) Pub. Date: Oct. 15, 2015

(54) COOLING SYSTEM FOR AN ELECTRICAL SYSTEM

(71) Applicant: Dr. Ing. h.c. F. Porsche Aktiengesellschaft, Stuttgart (DE)

(72) Inventor: Albert Schomerus, Bietigheim-Bissingen (DE)

(73) Assignee: Dr. Ing. h.c. F. Porsche Aktiengesellschaft, Stuttgart (DE)

(21) Appl. No.: 14/389,022

(22) PCT Filed: Dec. 20, 2012
(86) PCT No.: PCT/EP2012/005284

§ 371 Date: Sep. 29, 2014

(30) Foreign Application Priority Data
Mar. 29, 2012 (DE) 10 2012 102 719.6

(51) Int. Cl. H05K 7/20

(52) U.S. Cl. CPC H05K 7/2099

(57) ABSTRACT

A cooling system (100) for an electrical system (300) has at least one heat source (50) in the form of at least one electrical component (52) and a support structure (200) for absorbing mechanical loads. A heat transport device (10) is provided and has at least one heat pipe (20) with first and second ends (20a, 20b). The first end (20a) of the heat pipe (20) is coupled in a heat-transmitting manner with a first coupling device (22) on the heat source (50). The second end (22b) of the heat pipe (20) is coupled in a heat-transmitting manner with a second coupling device (24) on the support structure (200).

### BACKGROUND

1. Field of the Invention

The present invention relates to a cooling system for an electrical system.

2. Description of the Related Art

Cooling systems for electrical systems are basically known. They are usually used to conduct away waste heat from network devices in order to avoid damage to the network devices as a result of excessively high temperatures. It is therefore known that in the case of power supply units of electrical systems not only active power but also dissipated power is produced. In the case of power supply units in the region of 400 watts rated power, for example dissipated power of up to approximately 80 watts is produced and has to be conducted away essentially as heat. Known electrical systems have for this purpose cooling systems which are usually embodied as heat sinks directly at the electrical system or at an electrical component of the electrical system. Such heat sinks are frequently provided with cooling fins in order to maximize the surface of such a heat sink. Nevertheless, it is to a certain extent not possible to conduct away the necessary heat flow via the increased surface. Accordingly, in known electrical systems it is frequently necessary to bring about forced convection of the surrounding air in the region of the cooling fins. For this purpose, fan devices are used which, on the one hand, require additional installation space and, on the other hand, generate noise emissions during operation. Such a system is correspondingly relatively noisy. For example, DE 10 2008 054 958 A1 discloses such a device for use in the field of motor vehicles.

It is disadvantageous in known systems that, in addition to the necessary forced convection by the fan and the corresponding noise, a relatively large installation space is necessary for such electrical systems. In particular in the case of relatively high dissipated power levels and the corresponding large quantity of heat which has to be conducted away, large heat sinks and/or large forced convection systems in the form of ventilation systems are necessary. In particular, in the case of use for display devices this space problem is of decisive importance since space for large heat sinks cannot be made available in any way that is desired. The large amount of noise produced by the fans, in particular in the case of displays on the display device with low sound or without sound, is perceived as disruptive, while in the case of an application in a vehicle this is not the case owing to the driving noise.

The object of the present invention is to at least partially overcome the disadvantages of known cooling systems for electrical systems which are described above. In particular, the object of the present invention is to make available a cooling system for an electrical system, a cooling system for a display device and a display device having a cooling system, which cooling system can make available efficient cooling of the electrical system, in particular in the case of a display device, in a cost-effective, simple and space-saving fashion.

### SUMMARY OF THE INVENTION

A cooling system according to the invention for an electrical system has at least one heat source in the form of at least one electrical component. Furthermore, a supporting structure, in particular for taking up mechanical loads, is provided. A heat-transporting device is also provided which is equipped with at least one heat pipe. The heat pipe has a first coupling device at its first end and a second coupling device at its second end. The heat pipe is coupled in a heat-transmitting fashion to the heat source via the first coupling device and to the supporting device via the second coupling device. The heat-transporting device therefore produces the heat-transmitting connection between the supporting structure, on the one hand, and the heat source, on the other. Furthermore, the heat source has a carrier plate to which the at least one electrical component is attached in a heat-transmitting fashion and to which the first coupling device is coupled. This carrier plate serves, in particular, as a collecting device for heat from the at least one electrical component. In particular when more than one electrical component is used, that is to say in the case of two or more electrical components, this carrier plate can serve for collecting the waste heat of all the electrical components. The collected heat can be transferred to a single heat pipe via a single first coupling device. As a result, even in the case of complex designs of the heat source the complexity for a cooling system according to the invention can be kept as low as possible. By virtue of the provision of the carrier plate the position or the location of the coupling of the first coupling device can also be moved so that the positioning flexibility for the positioning of the heat source, in particular of the electrical components, is also increased here. Of course, within the scope of the present invention it is also possible to use more than one heat pipe for a heat-transporting device. In this context, each heat pipe has a corresponding first and second coupling device.

The heat source in the form of at least one electrical component can be, in particular, a power supply unit. If such a power supply unit is located within a frame of a display device, a separate heat sink no longer has to be provided with a cooling system according to the invention. The cooling is made available by an already present component, specifically the supporting structure. The supporting structure therefore preferably carries out a double function according to the present invention. The supporting structure is therefore configured, on the one hand, to carry out the supporting structure function, that is to say, in particular, the taking up of mechanical loads. In addition to this mechanical function, a technical heat function is carried out, specifically the conducting away of the heat from the heat source. As a result, the heat made available by the heat-transporting device can be conducted away in a desired fashion by the supporting structure over its entire surface. Since a supporting structure has, in particular for taking up mechanical loads, a relatively large mass and/or a relatively large surface, separate heat sinks for transporting away at least a portion of the heat are no longer necessary. With a cooling system according to the invention the compactness of the electrical system, in particular of the heat source in the form of at least one electrical component, is therefore increased. In the case of a display device, a supporting frame can be embodied as the supporting structure according to the present invention.

The conduction away of the heat from the electrical component or the heat source takes place in a particularly positive and fast fashion by means of the heat pipe. A heat pipe has particularly low heat conducting resistances for the transmission of heat. For this purpose, at least one interior space which is filled with a working medium is provided in the interior of the heat pipe. The working medium is provided both in the gaseous and in the liquid aggregate state in the interior space of the heat pipe. The liquid part of the working medium is located in the region of the heat source and is vaporized when heat is applied from the heat source. In the gaseous aggregate state, the working medium moves in the direction of the heat sink through convection, that is to say in the present invention in the direction of the second coupling device and can condense there on the outer wall of the heat pipe. The condensate is fed back in the direction of the heat source in the interior of the heat pipe. This recirculation can also take place by means of forced convection, for example by means of a gravity feed. Other feed systems, for example in the form of capillaries, are also conceivable within the scope of the present invention.

In a cooling system according to the invention in particular a cost-effective fluid is used as the working medium. This may be, for example, water, in particular distilled water, or a similar fluid. The working temperatures of the electrical components of the heat source are preferably below approximately 100° C. In particular, permissible maximum temperatures for the electrical components of up to approximately 90° C. are to be taken into account. Accordingly, the associated quantity of heat which is necessary to undershoot this maximum temperature by conducting away heat via the heat-transporting device can also be calculated.

A supporting structure according to the present invention can also be composed of a plurality of individual structure components. These can be combined to form a supporting structure which can also be embodied as a frame or frame structure. If a cooling system according to the invention is in use in a display device, the supporting structure is preferably at least components of a supporting frame structure of the display device.

The supporting structure or individual structure components of the supporting structure act in this way in particular as a heat sink of the cooling system. As a result, the mass and/or the surface which is present and necessary for the mechanical function of the supporting structure can serve in a double function as a secondary function for conducting away the heat which is fed in by the heat-transporting device.

An electrical system can be, for example, a battery-charging device or a power supply, in particular for a display device. Power converters or power electronics are also an electrical system according to the present invention.

A cooling system according to the invention can be developed in such a way that the first coupling device and/or the second coupling device have connecting means for the mechanical connection to the heat source and/or the supporting structure. Such connecting means may be, for example, rivets, screws or pin connections. They serve to make available not only the heat-transmitting coupling but also mechanical coupling between the heat source and the first coupling device or the supporting structure and the second coupling device. This ensures that even during operation of the cooling system the desired heat-transmitting coupling is maintained. The connecting means may also be embodied, for example, in a nonreversible fashion by virtue of the fact that they are preferably embodied as bonding faces or welding seams. In particular, the two coupling devices are provided with surface contacts which are embodied in particular as planar surface contacts with the heat source and/or the supporting structure. These surface contacts are positioned with the desired contact pressure via the connecting means such that as far as possible no air gap or only a small air gap remains between the surface contacts. Such an air gap would otherwise act in a heat-insulating fashion and impede the transmission of heat from the heat-transporting device or into the heat-transporting device.

A further advantage is also achieved in that with a cooling system according to the invention the heat pipe has at least in certain sections a closed-off interior space in which a working medium is contained in a partially gaseous fashion and a partially liquid fashion. A closed-off interior space is to be understood here as meaning, in particular, an interior space which is surrounded by a jacket and which is formed within a housing of the heat pipe. The heat pipe has preferably water, in particular distilled water, or a water mixture, as a working medium in its interior space. The liquid is preferably provided in the region of the heat source and the gas or gas/liquid mixture (vapor) is provided in the region of the heat sink. In this way, transportation of heat can take place with particularly little heat-conducting resistance, specifically by convection of the gaseous working medium and condensation of the working medium in the region of the heat sink.

According to the invention it is also possible that in a cooling system according to the invention the heat pipe has at least in certain sections in its interior space a capillary device which permits recirculation of condensed working medium in the interior of the heat pipe in the direction of the heat source independently of gravity. Such a capillary device can have, in particular, a wick or a wick system. This capillary device serves to allow the heat pipe or the heat-transporting device to be positioned even more flexibly in a cooling system according to the invention. This gives rise to easier selection of the arrangement of the heat source in the interior of a display device or in relation to the supporting structure. In particular, in this way heat-transporting devices can also be used transversely with respect to the direction of gravity or in opposition thereto. This increases the flexibility of the arrangement of a cooling system according to the invention further. The heat pipe itself is preferably of flexible design at least in certain sections. It therefore serves additionally for decoupling vibrations between the heat source, on the one hand, and the supporting structure, on the other. Furthermore, in this way compensation of thermal expansion, for production tolerances and deformations due, for example, to twisting.

It is also advantageous if in a cooling system according to the invention at least one electrical component is a power electronics component, in particular in the form of a brick module. A transformation preferably takes place in the power electronics component. For example, it can be an inverter or a rectifier which, in particular, rectifies alternating current to form direct current or direct current to form direct current. Direct coupling of this power electronics component to the heat pipe of the heat-transporting device via the first coupling device is also conceivable. In this embodiment, there is no need for a separate heat sink for the individual power electronics components. If this power electronics component has connecting faces for a heat sink, these connecting faces can be used for coupling the first coupling device. The brick module is a particularly preferred embodiment of the power electronics component, since it can be manufactured and used particularly cost-effectively by virtue of standard dimensions.

According to the invention it is also possible if in the cooling system a heat-transmitting medium, in particular a heat-transmitting paste, is arranged, at least in certain sections, between the first coupling device and the heat source and/or between the second coupling device and the supporting structure. Such a heat-transmitting means, in particular in the form of a heat-transmitting paste, serves to set the distance between the respective coupling device and the heat source or the supporting structure in such a way that an air gap between the two adjacent components is avoided completely or essentially completely. Furthermore, such a heat-transmitting means is intended to serve to reduce heat-transmitting resistances at the respective surface overall. In particular in the case of a corresponding material being selected for the coupling device and the heat source or the second coupling device and the supporting structure it is possible in this way to avoid an unfavorable material relationship of heat-transmitting resistances. This leads to a situation in which local heat accumulation during the transmission of heat at one of the two coupling devices can be prevented.

A further advantage can be achieved if in the case of a cooling system according to the invention the supporting structure is formed from a metallic substance. In particular, the substance may have at least one of the following materials aluminum, steel, stainless steel or cast iron material.

Provision of a metallic substance for the supporting structure entails the advantages that these materials have relatively high heat-conducting capabilities and associated low heat-conducting resistances. Furthermore, the metallic construction also serves to make available the primary functionality of the supporting structure, specifically the necessary mechanical stability.

Cooling systems according to the invention can be developed in such a way that the supporting structure is embodied as a frame or as a frame section of a display device.

It is a further advantage if in a cooling system according to the invention the heat source, in particular a carrier plate and/or the at least one electrical component have/has a contact face for coupling to the first coupling device in a heat-transmitting fashion. A contact face is here, in particular, a planar or essentially planar face. The orientation of the contact face or the geometric formation of this contact face preferably corresponds to a corresponding opposing contact face of the first coupling device. It is therefore preferably possible here for positive engagement to be brought about, which for the most part entirely avoids an air gap between the contact face of the heat source and the first coupling device. The contact face is preferably made as large as possible in order to be able to make available sufficiently good heat-transmitting contact for the transmission of sufficiently large heat flows.

It is furthermore advantageous if in a cooling system according to the invention the supporting structure has a contact face for coupling to the second coupling device in a heat-transmitting fashion. As already described in the paragraph above, the same advantages can also be achieved in the case of the heat-transmitting contact between the supporting structure and the second coupling device by a corresponding contact face.

A further advantage is achieved if in a cooling system according to the invention the first coupling device and/or the second coupling device are additionally designed to couple in an electrically conductive fashion. For example, one of the two coupling devices here can be a plug or a plug-type contact. If, for example, the first coupling device is coupled to a power supply unit at a socket, the second coupling device can be embodied at the opposite end as a plug for a supply socket of a display device. Through the additional embodiment of the heat-transporting device in the form of a heat pipe, the heat from the power supply unit is transferred in this way into the frame of the display device, with the result that a heat sink on the power supply unit can be completely avoided. The display device or the frame of the display device serves in this way to conduct away the heat which is generated by the power supply unit.

It is a further advantage if in the cooling system according to the invention the supporting structure is embodied at least in certain parts with a planar or essentially planar surface. This reduces the structural and technical material expenditure on the supporting structure. Furthermore, the mechanical stability is improved since notching effects and notches are avoided or reduced.

A cooling system for a display device, having at least one heat source in the form of at least one electrical component, a supporting structure, in particular for taking up mechanical loads, and a heat-transporting device having at least one heat pipe which is coupled in a heat-transmitting fashion at its first end to a first coupling device at the heat source and at its second end to a second coupling device at the support structure is also a subject matter of the present invention. This cooling system is embodied, in particular, according to the invention and therefore provides the same advantages as have been explained in detail with respect to the cooling system according to the invention for an electrical system.

A further subject matter of the present invention is a display device having a cooling system for an electrical system, having at least one heat source in the form of at least one electrical component, a supporting structure, in particular for taking up mechanical loads, and a heat-transporting device having at least one heat pipe which is coupled in a heat-transmitting fashion at its first end to a first coupling device at the heat source and at its second end to a second coupling device at the supporting structure. The cooling system is preferably embodied according to the invention. As a result, a display device according to the invention provides the same advantages as have been explained in detail with respect to a cooling system according to the invention. Such a display device can be, for example, a monitor or a plurality of monitors. The use of a plurality of individual display modules, in particular LED modules, as a display device is conceivable within the scope of the present invention. This involves, in particular, large image displays, for example on the stage, and advertising displays or the like.

The invention above is explained in more detail with reference to the appended figures in the drawing. The terms “on the left”, “on the right”, “top” and “bottom” used here relate to an orientation in the figures in the drawing with normally legible reference numerals.

### BRIEF DESCRIPTION OF THE DRAWINGS

FIG. 1 shows a first embodiment of a cooling system according to the invention.

FIG. 2 shows a second embodiment of a cooling system according to the invention.

FIG. 3 shows a third embodiment of a cooling system according to the invention.

FIG. 4 shows a fourth embodiment of a cooling system according to the invention.

### DETAILED DESCRIPTION

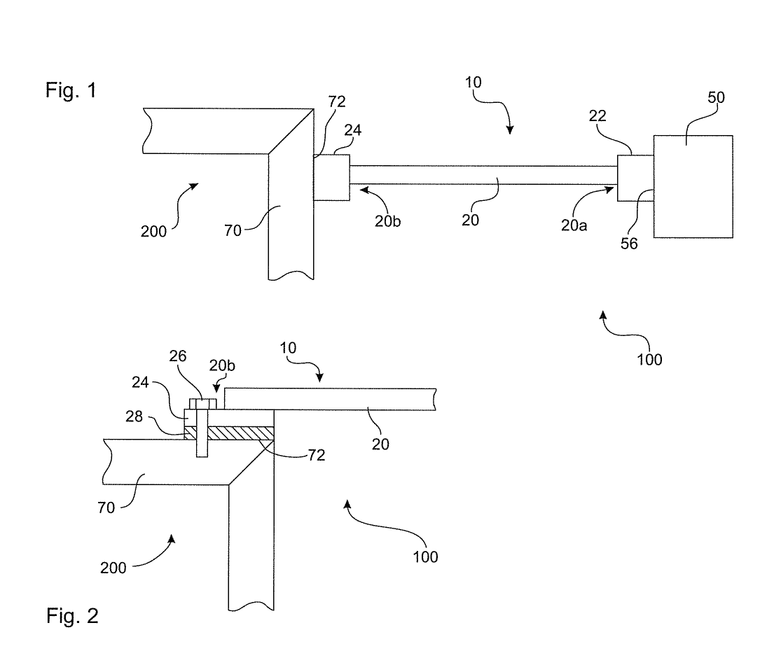

FIG. 1 illustrates a first embodiment of a cooling system 100 according to the invention. This embodiment has a heat-transporting device 10 which is designed to transmit heat from a heat source 50 to a structural component 70 of a supporting structure 200. In order to be able to carry out this transmission of heat or this transfer of heat, the heat-transporting device 10 is embodied with a heat pipe 20. This heat pipe 20 has an interior space which is filled with a working medium. The working medium is present in an essentially fluid state at a first end 20a of the heat pipe 20. At the opposite second end 20b of the heat pipe 20, the working medium is present in an essentially gaseous form in the interior space with the result that it can condense on the inner walls of the heat pipe 20 at the second end 20b.

In order to be able to transmit the heat from the heat source 20 to the supporting structure 200 in a desired fashion, the heat pipe 20 is embodied with a first coupling device 22 at a first end 20a. Furthermore, the heat pipe 20 has at its second end 20b a second coupling device 24. The first coupling device 22 is coupled in a heat-transmitting fashion to the heat source 50. Here, this coupling device 22 enters into heat-transmitting contact with the contact face 56 of the heat source 50 and can conduct waste heat away from the heat source 50 via this contact face 56. After the transfer within the heat pipe by vaporization and condensation of the working medium in the interior of the heat pipe, the heat is output to the supporting structure 200 via the second coupling device 24 via the contact face 72 of the structural component 70.

The supporting structure 200 is embodied in the fashion indicated as a frame, in particular as a frame or structural frame of a display device. The individual structural components 70 can be integral structural components of the supporting structure 200. They can also be separate components which are combined to form a common supporting structure 200 by screwing, riveting or welding.

FIG. 2 illustrates a portion of a further embodiment of a cooling system 100 according to the invention. In this embodiment, the connection of the second coupling device 24 at the second end 20b of the heat pipe 20 to the supporting structure 200 is illustrated in a relatively large illustration. In other words, the heat sink of the heat-transporting device 10 is illustrated here. The second coupling device 24 is attached to the supporting structure 200, in particular screwed, using a connecting means 26, in the form of a screw in this embodiment. Alternatively, a rivet pin or a connecting pin can also be used as a connecting means 26.

In the embodiment in FIG. 2, a heat-transmitting medium 28 is additionally provided for improving the transfer of heat between the second coupling device 24 and the supporting structure 200, in particular the structural component 70. Said heat-transmitting medium 28 may be provided, for example, as a heat-transmitting paste, with the result that an air gap between the second coupling device 24 and the structural component 70 of the supporting structure 200 can be avoided or substantially avoided. The contact face 72 on which the heat-transmitting medium 28 for the heat-transmitting coupling to the second coupling device 24 is located can also be seen in FIG. 2.

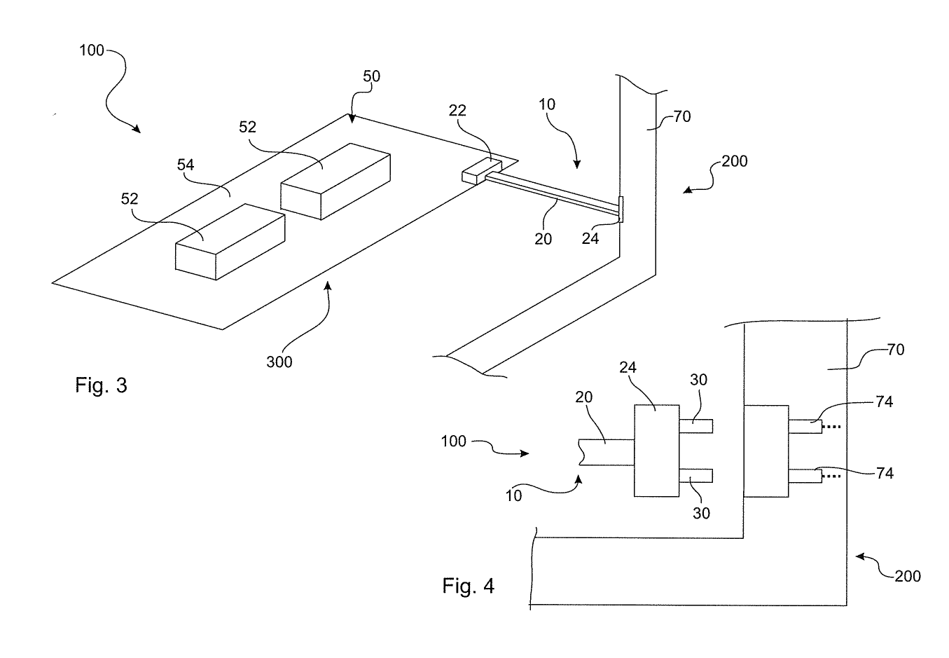

FIG. 3 illustrates a further embodiment of a cooling system 100 according to the invention. In this embodiment, a plurality of electrical components 52, specifically two electrical components 52, are provided. They are arranged on a common carrier plate 54 and in this way together form the heat source 50. The carrier plate 54 can also serve as a collecting plate for the heat generated by the individual electrical components 52. The heat generated by the electrical components 52 is therefore distributed via the carrier plate 54, in particular conducted in the direction of the coupling to the first coupling device 22. In this embodiment it is therefore possible for a single heat-transporting device 10 with a single heat pipe 20 to be sufficient to conduct away the waste heat despite more than one electrical component 52. The conduction away occurs here also via the heat pipe 20 to a second coupling device 24 for coupling to the structural component 70 of a supporting structure 200. This supporting structure 200 is also designed here to support mechanical loads, for example as a frame structure of a display device.

FIG. 4 illustrates a further embodiment of a cooling system 100 according to the invention. Here, the heat-transporting device 10 is equipped with an additional functionality. The heat-transporting device 10, in particular the heat pipe 20, is therefore embodied with an electrically conductive function. Electrical contacts 30 are additionally provided on the second coupling device 24. Electrical contact between the second coupling device 24 and electrical components 74 of the structural component 70 of the supporting structure 200 can be achieved via these electrical contacts 30. In other words, the second coupling device 24 can be embodied as a plug which is plugged into a corresponding plug-type contact of the supporting structure 200. If the supporting structure 200 is, for example, part of a display device, the corresponding contact plug device for the second coupling device 24 can be embodied as a supply socket of a display device.

The above explanation of the embodiments describes the present invention only within the scope of examples. Of course, individual features of the embodiments can, where technically appropriate, be freely combined with one another without departing from the scope of the present invention.

### LIST OF REFERENCE NUMERALS

10 Heat-transporting device
20 Heat pipe
20a First end
20b Second end
22 First coupling device
24 Second coupling device
26 Connecting means
28 Heat-transmitting medium
30 Electrical contact
50 Heat source
52 Electrical component
54 Carrier plate
56 Contact face
70 Structural component
72 Contact face
74 Electrical component
100 Cooling system
200 Supporting structure
300 Electrical system

1. A cooling system (100) for an electrical system (300), having at least one heat source (50) in the form of at least one electrical component (52), a supporting structure (200) for taking up mechanical loads, and a heat-transporting device (10) having at least one heat pipe (20), the heat pipe (20) having a first end (20a) coupled in a heat-transmitting fashion to a first coupling device (22) at the heat source (50) and having a second end (20b) coupled in a heat transmitting fashion to a second coupling device (24) at the supporting structure (200), wherein the heat source (50) has a carrier plate (54) to which the at least one electrical component (52) is attached in a heat-transmitting fashion and to which the first coupling device (22) is coupled.

2. The cooling system (100) of claim 1, wherein at least one of the first coupling device (22) and the second coupling device (24) has a connector (26) for mechanical connection to at least one of the heat source (50) and the supporting structure (200).

3. The cooling system (100) of claim 1, wherein the heat pipe (20) has at least in certain sections a closed-off internal space containing a working medium in a partially gaseous and a partially liquid state.

4. The cooling system (100) of claim 3, wherein the heat pipe (20) has a capillary device at least in certain sections in its interior space, the capillary device permitting recirculation of condensed working medium in the interior of the heat pipe (20) in a direction of the heat source (50) independently of gravity.

5. The cooling system (100) of claim 1, wherein the at least one electrical component (52) comprises a power electronics component in the form of a brick module.

6. The cooling system (100) of claim 1, further comprising a heat-transmitting paste arranged, at least in certain sections, between the first coupling device (22) and the heat source (50) and/or between the second coupling device (24) and the supporting structure (200).

7. The cooling system (100) of claim 1, wherein the supporting structure (200) is constructed of a metallic material, and has at least one of:
aluminum
steel
stainless steel
cast iron material.

8. The cooling system (100) of claim 1, wherein the supporting structure (200) is at least part of a frame of a display device.

9. the cooling system (100) of claim 1, wherein the heat source (50) has a contact face (56) for coupling to the first coupling device (22) in a heat-transmitting fashion.

10. The cooling system (100) of claim 1, wherein the supporting structure (200) has a contact face (72) for coupling to the second coupling device (24) in a heat-transmitting fashion.

11. The cooling system (100) of claim 1, wherein at least one of the first coupling device (22) and the second coupling device (24) is designed for coupling in an electrically conductive fashion.

12. The cooling system (100) of claim 1, wherein the supporting structure (200) has an essentially planar surface.

13. A cooling system (100) for a display device, comprising at least one heat source (50) in the form of at least one electrical component (52), a supporting structure (200), for taking up mechanical loads, and a heat-transporting device (10) having at least one heat pipe (20) with a first end (20a) coupled in a heat-transmitting fashion to a first coupling device (22) at the heat source (50) and a second end (20b) coupled in a heat-transmitting fashion to a second coupling device (24) at the supporting structure (200).

14. The cooling system (100) of claim 13, wherein the heat source (50) has a carrier plate (54) to which the at least one electrical component (52) is attached in a heat-transmitting fashion and to which the first coupling device (22) is coupled.

15. A display device having a cooling system (100) for an electrical system (300), comprising: at least one heat source (50) with at least one electrical component (52), a supporting structure (200) for taking up mechanical loads, and a heat-transporting device (20) having at least one heat pipe (20) with a first end (20a) coupled in a heat-transmitting fashion to a first coupling device (22) at the heat source (50) and a second end (20b) coupled in a heat-transmitting fashion to a second coupling device (24) at the supporting structure (200).

16. The display device as claimed in claim 15, wherein the heat source (50) has a carrier plate (54) to which the at least one electrical component (52) is attached in a heat-transmitting fashion and to which the first coupling device (22) is coupled.
